(19) United States
(12) Patent Application Publication
(10) Pub. No.: US 2008/0016421 A1
(43) Pub. Date: Jan. 17, 2008

(54) METHOD AND APPARATUS FOR PROVIDING PROGRAMMABLE CONTROL OF BUILT-IN SELF TEST

(75) Inventor: Hugh William McDevitt, San Jose, CA (US)

Correspondence Address: DAVID W. LYNCH;CHAMBLISS, BAHNER & STOPHEL, 1000 TALLAN SQUARE-S, TWO UNION SQUARE, CHATTANOOGA, TN, 37402, US

(73) Assignee: INTERNATIONAL BUSINESS MACHINES CORPORATION, Armonk, NY (US)

(21) Appl. No.: 11/457,457

(22) Filed: Jul. 13, 2006

(51) Int. Cl. G01R 31/28

(52) U.S. Cl. 714/733

(57) ABSTRACT

A method and apparatus provides programmable control of built-in self test. A programmable controller allows software selectively to run BIST on different ports of the complex circuit and examine the results. The programmable BIST controller is implemented to execute selected BIST operations, wherein software may choose to either enable or disable running of a particular BIST operation.

### BACKGROUND OF THE INVENTION

1. Field of the Invention

This invention relates in general to the testing and verification of complex integrated circuits, and more particularly to method and apparatus for providing programmable control of built-in self test.

2. Description of Related Art

Integrated circuits are becoming increasingly more complex as more core devices and supporting logic are integrated onto a single chip. This is driven, in part, from the need to provide increased functionality in less space, with lower power consumption and with higher bandwidths. These product performance requirements force integrated circuit designers to populate a single chip with several devices, which may include controllers, memory blocks, processors, and various input/output (I/O) interfaces to provide a complex integrated circuit.

In recent years, application-specific integrated circuit (ASIC) chips have evolved from a chip-set approach to an embedded cored based system-on-a-chip (SoC) approach. An SOC ASIC includes various reusable functional blocks. Such pre-designed functional blocks are commonly referred to as cores. With the increased complexity and density of today's high-end ASIC chips and higher-level electronic packages, there is a corresponding increase in the time required to verify the functionality of these complex core combinations. Furthermore, improvements in microprocessor performance have resulted in data transfer bandwidths that typically outpace I/O transfer rates. In the telecommunications industry, for example, high-speed telecommunications data is converted into multiple low-speed T1 data paths for transmission and then reconverted to the high-speed data at the receiver. As another example, analog signals are routinely converted to a digital signal, transmitted, and then reconverted back to the analog signal.

Similarly, parallel data I/O bus bottlenecks result in performance compromises in peripheral and network interfaces, and accordingly have spurred the development of high-speed serial transfer methods. As the load of a conventional PCI device became greater, third generation input/output (3GIO) replaced the PCI interface to provide the greater bandwidth requirement. The third generation input/output (3GIO) is also known as a PCI Express interface. The PCI Express technology utilizes a higher operational clock and applies more data lanes to improve efficiency.

Unlike conventional protocols where data is transferred over multiple conducting traces or wires, a high-speed serial interface converts parallel data into a high-speed, serial data stream. The serial data stream is typically converted back to parallel data by a deserializer at a receiving peripheral device for application with the particular logic in that device. Integration of such I/O interfaces as part of a complex integrated circuit on a single chip is consistent with proximally locating the serializer/deserializer I/O with the devices that are either transmitting or receiving the data, thus avoiding I/O bus bandwidth limitations and enabling higher data transfer rates. The integration of increasing numbers of functional devices onto a single chip and the resulting complex interconnectivity requirements of these devices with other devices on and off the chip has resulted in the integration of high-speed serializer/deserializer I/O interface cores onto the chip containing the customers logic.

High levels of device integration onto a single chip, while reducing the chip count on a board, will increase the unit cost of the integrated circuit. This is principally due to lower manufacturing yields resulting from the increased process complexities associated with the manufacture of such highly integrated devices, as well as the yield impact attendant with the additional process steps required to fabricate these chips. Accordingly, it is well known that the likelihood of manufacturing defects increases as chip complexity increases. Core device tolerances become increasingly critical as the devices are packed closer together and are required to operate and interact at higher bandwidths. Deviation from these tolerances can cause defects in the chips resulting in lower process yields, increased screening of finished goods, resulting in higher per unit costs. Also, the additional process steps associated with the fabrication of these highly integrated circuits provide further opportunities for defects and thus increased cost due to lower manufacturing yields.

The high cost of manufacturing these complex integrated circuits makes it desirable, therefore, to identify product defects as early in the manufacturing process as possible, thus avoiding the expense of further processing an otherwise defective chip. In addition, early manufacturing rejection of defective parts reduces the amount of screening required of the finished product. Accordingly, where an I/O interface is incorporated as a core device on an integrated circuit, it is desirable to test the I/O interface during the manufacture, or as shortly thereafter as possible, of the integrated circuit to determine if the I/O interface is operating to specification before additional time and money are expended to complete the fabrication of what might otherwise be a defective device, or to avoid costs associated with installation of a defective device onto a board.

Typically, multiple independent built-in self-test (BIST) runs are needed to verify the internal logic of multiple functional packages of an ASIC. Many integrated circuit devices or chips support on-board Built-In Self-Test (BIST) logic that assist in diagnosing, and sometimes correcting, errors in a device. On-board scan registers are architected into the integrated circuit device to either insert or capture data at various internal nodes in a circuit. Arrays may be tested using Array BIST (ABIST) circuitry, while logic circuitry may be tested using Logical BIST (LBIST) circuitry. Moreover, built-in test circuitry for testing the operation of a high-speed serial interface has also been developed (HSS BIST). For example, BIST pattern generators can generate a compliance bit pattern, e.g., defined in the PCI Express specifications, to perform system-level diagnostics. Each of these types of circuitry is capable of being interfaced with a test scan interface for communication with an external device.

Complex integrated circuits, such as application-specific integrated circuits (ASICs), field programmable gate arrays (FPGAs), complex programmable logic devices (CPLDs), etc., implement Built-in Self Test (BIST) to allow testing of the functional packages in the system environment. Because typical complex circuits contain a variety of logic, arrays, and intellectual property implemented as hard and soft cores, a controller is required to implement the protocols necessary to run BIST on the entire chip. Moreover, it may be necessary or desirable to only run the BIST on selected ports of the complex circuit.

It can be seen that there is a need for a method and apparatus for providing programmable control of built-in self test.

### SUMMARY OF THE INVENTION

To overcome the limitations in the prior art described above, and to overcome other limitations that will become apparent upon reading and understanding the present specification, the present invention discloses a method and apparatus for providing programmable control of built-in self test.

The present invention solves the above-described problems by providing a programmable controller that allows software selectively to run BIST on different ports of the complex circuit and examine the results. The programmable BIST controller is implemented to execute selected BIST operations, wherein software may choose to either enable or disable running of a particular BIST operation.

A programmable built-in self test (BIST) controller in accordance with the principles of the present invention includes instructions for invoking selected BIST operations to execute on accessible cores.

In another embodiment of the present invention, an application specific integrated circuit is provided. The application specific integrated circuit includes a plurality of cores designed for performing a predetermined task, each of the plurality of cores having a built-in self test (BIST) engine for implementing BIST operations specific for the core, a test access port for providing an interface for receiving input form an external controller, the input identifying cores to be tested and a programmable BIST controller, coupled to the plurality of cores and the test access port, the programmable BIST controller including BIST control and instructions for invoking BIST operations on cores identified via the input received via the test access port.

In another embodiment of the present invention, a method of providing programmable BIST operations in an application specific integrated circuit is provided. The method includes forming a plurality of cores for performing designed tasks to an integrated circuit, embedding built-in self test (BIST) circuitry to each of the plurality of cores, providing, to the integrated circuit, a programmable BIST controller having instructions for selectively invoking BIST operations via the BIST circuitry in each of the cores, and determining which core to invoke BIST operations in and invoking BIST operations only in the determined cores.

These and various other advantages and features of novelty which characterize the invention are pointed out with particularity in the claims annexed hereto and form a part hereof. However, for a better understanding of the invention, its advantages, and the objects obtained by its use, reference should be made to the drawings which form a further part hereof, and to accompanying descriptive matter, in which there are illustrated and described specific examples of an apparatus in accordance with the invention.

### BRIEF DESCRIPTION OF THE DRAWINGS

Referring now to the drawings in which like reference numbers represent corresponding parts throughout:

FIG. 1 illustrates a conventional application-specific integrated circuit (ASIC);

FIG. 2 shows one embodiment of BIST circuitry for a core according to an embodiment of the present invention;

FIG. 3 illustrates an ASIC having a programmable BIST controller according to an embodiment of the present invention; and

FIG. 4 is a flow chart of a method for providing programmable BIST control for an ASIC according to an embodiment of the present invention.

### DETAILED DESCRIPTION OF THE INVENTION

In the following description of the embodiments, reference is made to the accompanying drawings that form a part hereof, and in which is shown by way of illustration the specific embodiments in which the invention may be practiced. It is to be understood that other embodiments may be utilized because structural changes may be made without departing from the scope of the present invention.

The present invention provides a method and apparatus for providing programmable control of built-in self test. The programmable BIST controller is implemented to execute selected BIST operations, wherein software may choose to either enable or disable running of a particular BIST operation.

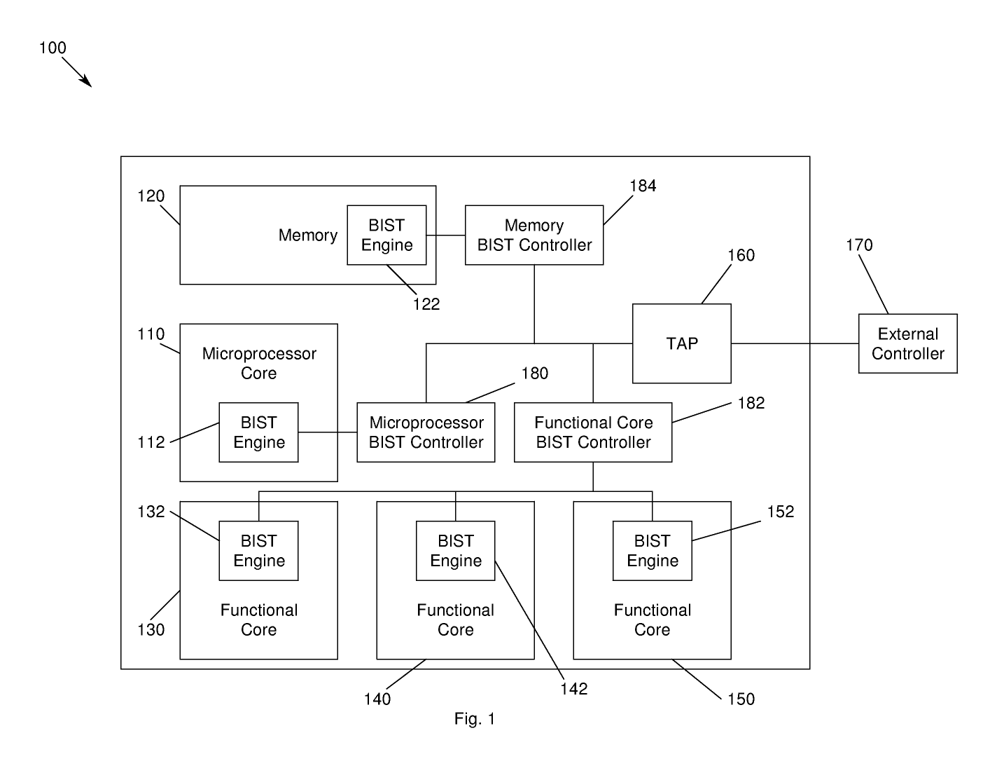

FIG. 1 illustrates a conventional application-specific integrated circuit (ASIC) 100. In FIG. 1, the ASIC 100 includes a microprocessor core 110, memory elements 120 and several function-specific cores 130, 140, 150, and a test access port 160 for providing an interface to a host or external controller 170. Built-in self test (BIST) 112, 122, 132, 142, 152 is added to cores 110, 120, 130, 140, 150 to verify the structural integrity of that design. BIST is a Design-for-Testability (DFT) technique, because it makes the electrical testing of a chip easier, faster, more efficient, and less costly. The concept of BIST is applicable to just about any kind of circuit, so its implementation can vary as widely as the product diversity that it caters to. BIST comes in many flavors, such as BIST-based testing of embedded SRAM devices, DRAM BIST, logic BIST, and BIST for analog and mixed-signal functions. These BIST techniques generally allow one or more functional blocks in ASIC 100 to be tested with relatively simple digital tester resources.

Depending upon the complexity of ASIC 100 and the need or desire to test functional cores 130, 140, 150, memory 120 and/or microprocessor core 110, BIST controllers 180-184 may be provided within the SOC during the chip's design. To perform a built-in self test, a host or an external controller 170 will instruct one of the BIST controllers 180-184 to supply a series of patterns to an applicable port of one of the cores 110, 120, 130, 140, 150 that is to be tested. These patterns are referred to as test algorithms. The operation of BIST controllers 180-184 involves exercising the functional cores 130, 140, 150, memory 120 and/or microprocessor core 110 according to their function, and after a period of time, determining whether the tested functional cores 130, 140, 150, memory 120 and/or microprocessor core 110 operated in an intended manner and with intended functionality.

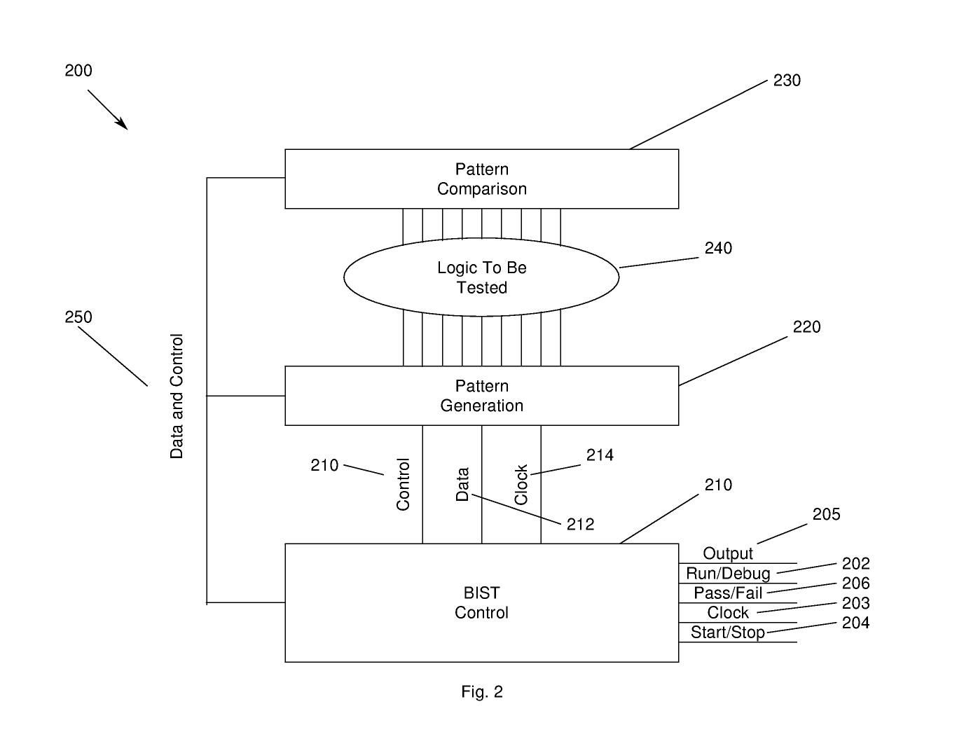

FIG. 2 shows one embodiment of BIST circuitry 200 for a core according to an embodiment of the present invention. In FIG. 2, a control section 210 communicates with a controller (not shown) to control when the BIST is run and signals completion of a test, pass/fail, etc. For example, a controller may supply a BIST control section 210 with a run/debug signal 202, a clock 203 and a start/stop signal 204. The control section 210 sets up a pattern generator 220 to apply the patterns via a control signal 212, data 214 and clock 216 and a pattern comparison 230 accepts data coming from the logic to be tested 240. The BIST control section 210 may provide an output signal 205 and an indication of pass/fail 206. The BIST control section 210 is coupled to the pattern generation 220 and pattern comparison via a data and control bus 250. Sometimes the logic to be tested 240 will have a “wrapper” or “collar” that is used to connect and disconnect the test logic to/from the BIST engine 200 and the rest of the ASIC logic.

The BIST techniques can be divided into categories. The two most common are logic BIST (LBIST), which is used to test at-speed the logic in the devices, and array BIST (ABIST), which is used to provide at-speed testing of the embedded arrays (i.e., RAMs). In the case wherein BIST circuitry 200 is a logic BIST engine, BIST control section 210 would thus instruct the pattern generator 210 to generate all necessary waveforms for repeatedly loading pseudorandom patterns into scan chains for the logic to be tested 240. The BIST control section 210 would then initiate a functional cycle (capture cycle) and log the captured responses. This test cycle is typically repeated many times with the results of each test cycle being combined in some manner with the results of the previous test cycles. The accumulated responses would be provided in a code known as a signature. The pattern comparison 230 would compare the signature to an expected signature to determine whether the logic to be tested 240 operated properly. Any corruption in the final signature at the end of the test indicates a defect in the chip.

In the case wherein BIST circuitry 200 is an Array BIST (ABIST) engine for testing the physical and logical structure of a memory array, the BIST control section 210 provides for bit-line stress testing, other case specific read-write combinations, data retention tests, etc. For the ABIST test, a BIST control section 210 is based on a programmable-state machine that is used to cause the pattern generation to algorithmically generate a variety of memory test sequences. As with LBIST, test patterns can be applied to the logic to be tested 240 at cycle speeds. Because of the regular structure of arrays, an ABIST engine can be shared among several arrays. This not only reduces the overhead per array, but also allows for decreased test times, since the arrays can be tested in parallel.

Functional cores may include a wide variety of functional elements such as peripheral cores, memory controllers, DMA engines, bus components, etc. One important type of functional core is a SERializer/DESerializer (SERDES) core. As networking architectures move forward, SERializer/DESerializer (SERDES) used in high speed communications to convert data from/to a serial data stream and a parallel data stream are being pushed to their maximum capabilities. Designers are being pushed to build more complex chips that handle increasingly fast data transmission rates. Thus, BIST circuitry 200 for testing functional cores, such as SERDES cores, makes it possible to develop higher speed products in shorter periods.

A SERDES design consists of a transmit data path, a receive data path, and a common block. In addition to these blocks a SERDES chip will usually have additional control logic and testability blocks to enhance test and characterization. Because the performance of a SERDES design often exceeds the performance of equipment needed to test it, BIST circuitry 200 needs to be included in the SERDES chip to ensure its testability.

Thus, a BIST circuit 200 may be provided into a functional core to verify the operation of the core. BIST functions in the form of pattern generation 220 and a corresponding pattern comparison 230 may be provided to test a function core such as a SERDES. For example, in the BIST mode, instead of the normal data inputs, a Serializer takes the parallel data from the BIST pattern generation 210 to generate the serial outputs. The pattern comparison 230 in the De-serializer checks the received data against an expected pattern to determine if there is any bit error. A SERDES can test itself by looping back the pattern from the Serializer to the De-serializer.

Besides the patterns, the BIST function can also include other data patterns that could provide additional diagnostic functions to what a SERDES has to offer. For example, the BIST pattern generator can generate the compliance pattern, defined in the PCI Express specifications, to make system-level diagnosis easier. By generating a constant 1's or 0's by the BIST pattern generation 220, DC level testing on the serial outputs can be easily performed

However, it is desirable to simply select which BIST tests to run rather than providing a BIST controller all of the control inputs. Further, it may be necessary or desirable to only run the BIST on selected ports of the complex circuit. Nevertheless, as described above with reference to FIG. 1, each controller 180-184 for the functional cores 130, 140, 150, memory 120 and microprocessor core 110 are separately initiated and controlled by the external host or external controller 170 through the test access port 160. Because typical complex circuits contain a variety of logic, arrays, and intellectual property implemented as hard and soft cores, a separate controller 180-184 has been used to implement the protocols necessary to run BIST on each type of core on the ASIC 100.

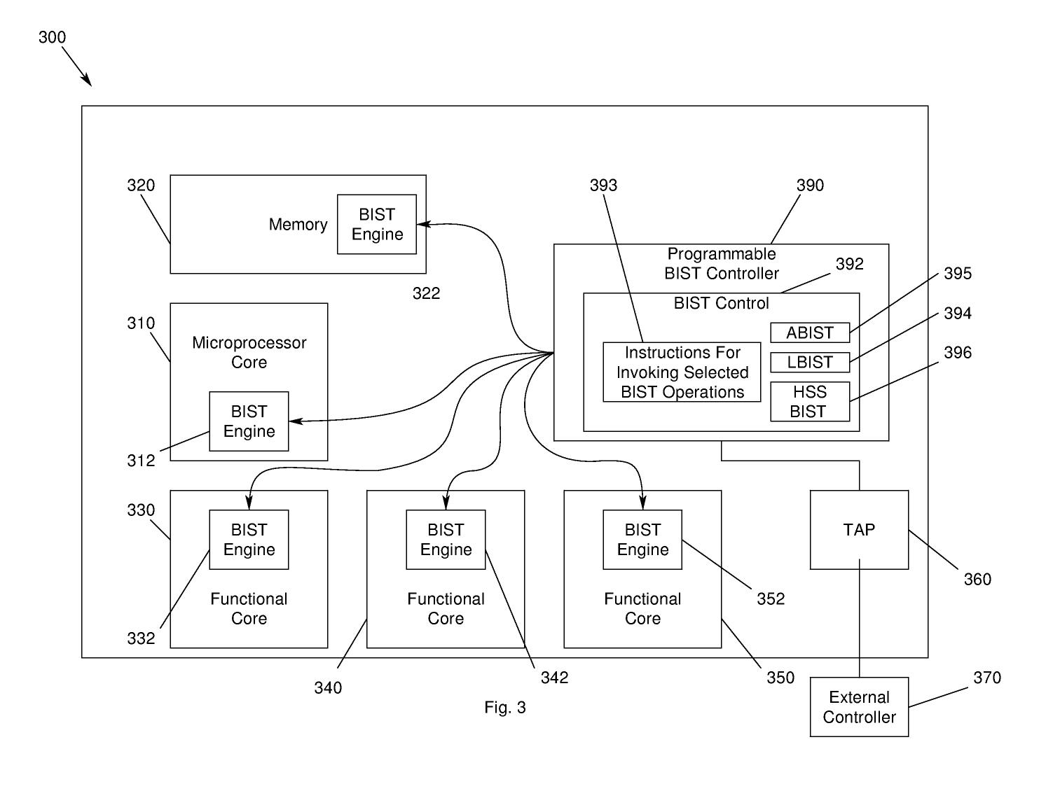

FIG. 3 illustrates an ASIC 300 having a programmable BIST controller 390 according to an embodiment of the present invention. In FIG. 3, the ASIC 300 includes a microprocessor core 310, memory elements 320 and several function-specific cores 330, 340, 350, a programmable BIST controller 390 and a test access port 360 for providing an interface to a host or external controller 370. Built-in self test (BIST) 312, 322, 332, 342, 352 is added to cores 310, 320, 330, 340, 350 to verify the structural integrity of that design. The programmable BIST controller 390 includes BIST control logic 391, which is configured with instructions 393 for invoking selected BIST operations to execute, for example, Logic BIST (LBIST) 394, Array BIST (ABIST) 395, and HSS BIST 396. In each case, software instructions 392 may be used to choose which BIST operation to enable or disable.

The programmable BIST controller 390, according to instructions 392 and input form external controller 370, initiates only BIST operations specified in the input from the external controller 370. The results are collected by the programmable BIST controller 390 for later processing. For example, the programmable BIST controller 390 may implement the specific interface protocols to run BIST on a High-Speed Serial Deserializer (HSS) core and further have the flexibility to enable or disable running the BIST operation to cores selected from the multiple cores 310, 320, 330, 340, 350 on the ASIC 300.

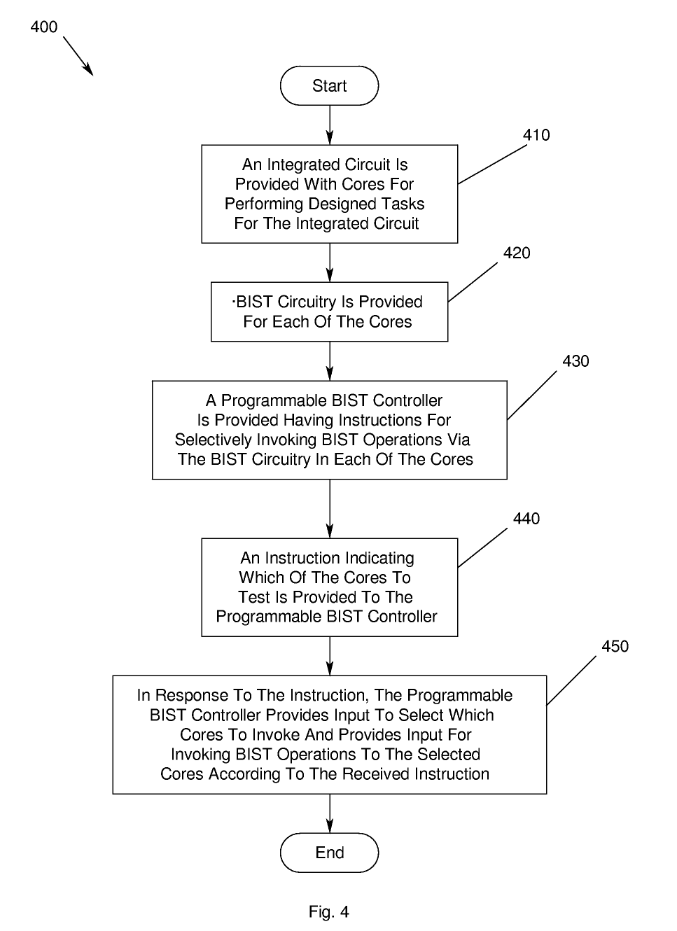

FIG. 4 is a flow chart 400 of a method for providing programmable BIST control for an ASIC according to an embodiment of the present invention. In FIG. 4, an integrated circuit is provided with cores for performing designed tasks for the integrated circuit 410. BIST circuitry is provided for each of the cores 420. A programmable BIST controller is provided having instructions for selectively invoking BIST operations via the BIST circuitry in each of the cores 430. An instruction indicating which of the cores to test is provided to the programmable BIST controller 440. In response to the instruction, the programmable BIST controller provides input to select which cores to invoke and provides input for invoking BIST operations to the selected cores according to the received instruction 450.

The foregoing description of the embodiment of the invention has been presented for the purposes of illustration and description. It is not intended to be exhaustive or to limit the invention to the precise form disclosed. Many modifications and variations are possible in light of the above teaching. It is intended that the scope of the invention be limited not with this detailed description, but rather by the claims appended hereto.

What is claimed is:

1. A programmable built-in self test (BIST) controller comprising BIST control including instructions for invoking selected BIST operations to execute on accessible cores.

2. The programmable BIST controller of claim 1, wherein the BIST control receives input from an external controller identifying selected cores to invoke BIST operations on.

3. The programmable BIST controller of claim 1, wherein the instructions of the BIST control invoke BIST operations on all cores in response to input from an external controller.

4. The programmable BIST controller of claim 1, wherein the instructions of the BIST control invoke only BIST operations for cores specified in the input from the external controller.

5. The programmable BIST controller of claim 1, wherein the instructions of the BIST control are used to process results collected from cores that were instructed to invoke BIST operations.

6. The programmable BIST controller of claim 1, wherein the instructions of the BIST control implement specific interface protocols to run BIST operations for each type of core to be tested by the programmable BIST controller.

7. The programmable BIST controller of claim 1, wherein the instructions of the BIST control implement interface protocols for performing logical BIST operations, array BIST operations and High-Speed Serial Deserializer (HSS) BIST operations.

8. The programmable BIST controller of claim 1, wherein the instructions of the BIST control disable running the BIST operation to cores selected by received input from an external controller.

9. An application specific integrated circuit, comprising:
a plurality of cores designed for performing a predetermined task, each of the plurality of cores having a built-in self test (BIST) engine for implementing BIST operations specific for the core;
a test access port for providing an interface for receiving input form an external controller, the input identifying cores to be tested; and
a programmable BIST controller, coupled to the plurality of cores and the test access port, the programmable BIST controller including BIST control and instructions for invoking BIST operations on cores identified via the input received via the test access port.

10. The application specific integrated circuit of claim 9, wherein the BIST control receives input from an external controller identifying selected cores to invoke BIST operations on.

11. The application specific integrated circuit of claim 9, wherein the instructions of the BIST control invoke BIST operations on all cores in response to input from an external controller.

12. The application specific integrated circuit of claim 9, wherein the instructions of the BIST control invoke only BIST operations for cores specified in the input from the external controller.

13. The application specific integrated circuit of claim 9, wherein the instructions of the BIST control are used to process results collected from cores that were instructed to invoke BIST operations.

14. The application specific integrated circuit of claim 9, wherein the instructions of the BIST control implement specific interface protocols to run BIST operations for each type of core to be tested by the programmable BIST controller.

15. The application specific integrated circuit of claim 9, wherein the instructions of the BIST control implement interface protocols for performing logical BIST operations, array BIST operations and High-Speed Serial Deserializer (HSS) BIST operations.

16. The application specific integrated circuit of claim 9, wherein the instructions of the BIST control disable running the BIST operation to cores selected by received input from an external controller.

17. A method of providing programmable BIST operations in an application specific integrated circuit, comprising:
forming a plurality of cores for performing designed tasks to an integrated circuit;
embedding built-in self test (BIST) circuitry to each of the plurality of cores;
providing, to the integrated circuit, a programmable BIST controller having instructions for selectively invoking BIST operations via the BIST circuitry in each of the cores; and
determining which core to invoke BIST operations in and invoking BIST operations only in the determined cores.

18. The method of claim 17, wherein the determining which core to invoke BIST operations in and invoking BIST operations only in the determined cores further comprising receiving by the programmable BIST controller an instruction indicating which of the cores to test and in response to the instruction, selecting by the programmable BIST controller which cores to invoke and providing input for invoking BIST operations to the selected cores according to the received instruction.

19. The method of claim 17 further comprising processing results collected from cores that were instructed to invoke BIST operations.

20. The method of claim 17, wherein the providing, to the integrated circuit, a programmable BIST controller having instructions for selectively invoking BIST operations via the BIST circuitry in each of the cores further comprises providing the programmable BIST controller specific interface protocols to run BIST operations for each type of core to be tested by the programmable BIST controller.
